(19) United States
(12) Patent Application Publication
(10) Pub. No.: US 2026/0107700 A1
(43) Pub. Date: Apr. 16, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Dong Yeol YUN, Icheon-si (KR); Tae Hyung Park, Icheon-si (KR); Jeong Ho Yeon, Icheon-si (KR)

(21) Appl. No.: 19/185,869

(22) Filed: Apr. 22, 2025

(30) Foreign Application Priority Data
Oct. 11, 2024 (KR) 10-2024-0138651

(51) Int. Cl. H10N 70/00; H10B 63/10; H10N 70/20

(52) U.S. Cl. CPC H10N 70/841; H10B 63/10; H10N 70/063; H10N 70/231; H10N 70/882

(57) ABSTRACT

A semiconductor device include a first conductive line extending in a first direction, a second conductive line positioned on the first conductive line and extending in a second direction intersecting the first direction, and a memory cell positioned between the first conductive line and the second conductive line, and including a lower electrode pattern, an upper electrode pattern positioned on the lower electrode pattern, and a variable resistance pattern positioned between the lower electrode pattern and the upper electrode pattern, and the upper electrode pattern may include a first portion positioned between the variable resistance pattern and the second conductive line, and a pair of second portions extending on sidewalls of the variable resistance pattern that face each other and are arranged in the second direction, such that an interface between the first portion and the variable resistance pattern is located between the second portions.

### CROSS-REFERENCE TO RELATED APPLICATION

This application claims priority under 35 U.S.C. § 119 to Korean Patent Application No. 10-2024-0138651 filed on Oct. 11, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The degree of integration of a semiconductor device is mainly determined by an area occupied by a unit memory cell. Recently, as improvement in the degree of integration of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a first conductive line extending in a first direction, a second conductive line positioned on the first conductive line and extending in a second direction that intersects the first direction, and a memory cell positioned between the first conductive line and the second conductive line, and including a lower electrode pattern, an upper electrode pattern positioned on the lower electrode pattern, and a variable resistance pattern positioned between the lower electrode pattern and the upper electrode pattern. The upper electrode pattern may include a first portion positioned between the variable resistance pattern and the second conductive line, and a pair of second portions extending on first sidewalls of the variable resistance pattern that face each other and are arranged in the second direction, such that an interface between the first portion and the variable resistance pattern is located between the second portions.

According to an embodiment of the present disclosure, a semiconductor device may include a first conductive line extending in a first direction, a second conductive line positioned on the first conductive line and extending in a second direction that intersects the first direction, and a memory cell positioned between the first conductive line and the second conductive line, and including a lower electrode pattern, an upper electrode pattern positioned on the lower electrode pattern, and a variable resistance pattern positioned between the lower electrode pattern and the upper electrode pattern. The upper electrode pattern may include a first portion positioned between the variable resistance pattern and the second conductive line, a pair of second portions extending on first sidewalls of the variable resistance pattern that face each other and are arranged in the second direction, and a pair of third portions extending on second sidewalls of the variable resistance pattern that face each other and are arranged in the first direction. The second portions and the third portions of the upper electrode pattern surround an interface between the first portion and the variable resistance pattern.

According to an embodiment of the present disclosure, a method of manufacturing a semiconductor device may include sequentially forming a lower electrode layer, a variable resistance layer, and an upper electrode layer on a first conductive layer, forming upper electrode lines extending in a first direction by etching the upper electrode layer, etching the variable resistance layer to a partial thickness, forming a first additional electrode layer along a profile of the upper electrode lines and the variable resistance layer, and forming variable resistance lines by etching the variable resistance layer.

### BRIEF DESCRIPTION OF THE DRAWINGS

FIGS. 1A, 1B, and 1C are drawings illustrating a semiconductor device according to an embodiment of the present disclosure.

FIGS. 2A, 2B, 3A, 3B, 4A, 4B, 5A, 5B, 6A, 6B, 7A, 7B, 8A, 8B, 9A, 9B, and 9C are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to an embodiment of the present disclosure, a semiconductor device having a stable structure and improved reliability may be provided. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B). Moreover, a first element “on” a second element indicates that the first element can be “directly on” the second element, or that at least one intervening element can be interposed between the first and second elements.

Hereinafter, some embodiments of the present disclosure are described with reference to the accompanying drawings.

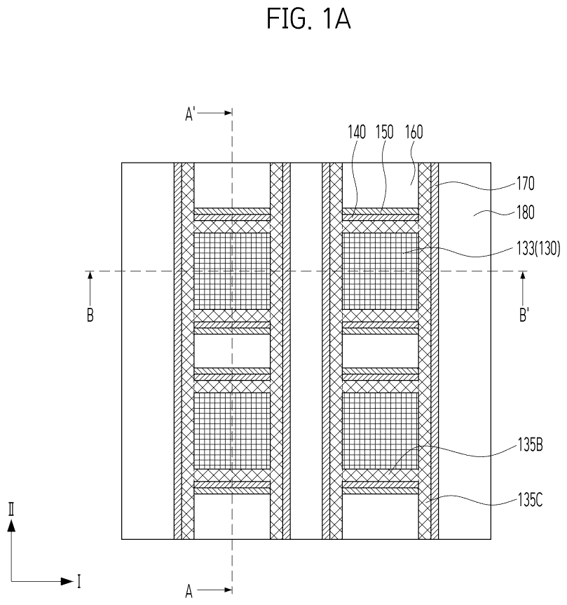

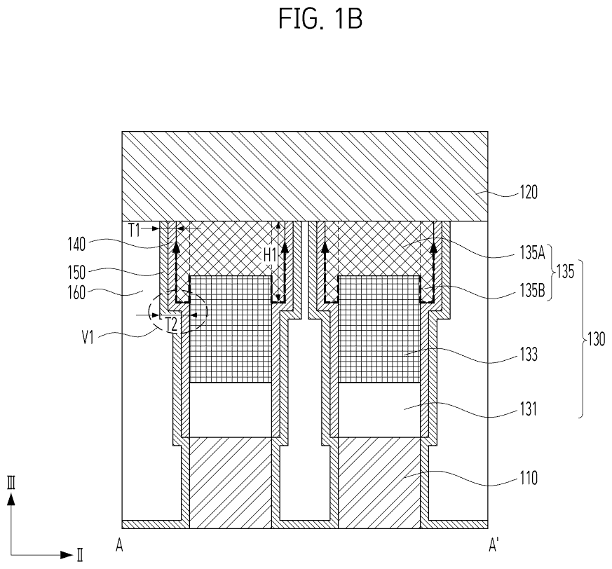

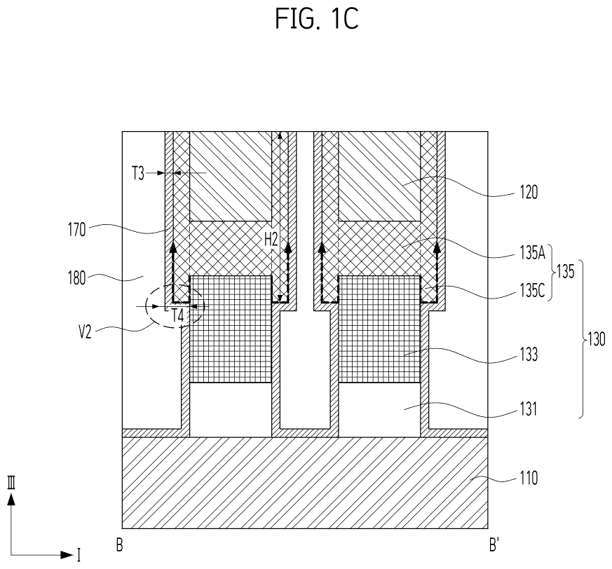

FIGS. 1A to 1C are drawings illustrating a semiconductor device according to an embodiment of the present disclosure. FIG. 1A is a plan view, FIG. 1B is a cross-sectional view taken along line A-A′ of FIG. 1A, FIG. 1C is a cross-sectional view taken along line B-B′ of FIG. 1A.

Referring to FIGS. 1A to 1C, the semiconductor device may include first conductive lines 110, second conductive lines 120, and memory cells 130. The semiconductor device may further include first liner patterns 140, second liner patterns 150, first gap-fill patterns 160, third liner patterns 170, and second gap-fill patterns 180.

The first conductive lines 110 may each extend in a first direction I. The second conductive lines 120 may intersect the first conductive lines 110 and may be positioned on the first conductive lines 110. The second conductive lines 120 may each extend in a second direction II intersecting the first direction I. For example, the first conductive lines 110 may each be a word line, and the second conductive lines 120 may each be a bit line. As another example, the first conductive lines 110 may each be a bit line, and the second conductive lines 120 may each be a word line.

The memory cells 130 may be arranged in the first direction I and the second direction II. The memory cell 130 may be positioned between the first conductive line 110 and the second conductive line 120. The memory cell 130 may include a lower electrode pattern 131, a variable resistance pattern 133, and an upper electrode pattern 135.

The lower electrode pattern 131 may be positioned on the first conductive line 110. The lower electrode pattern 131 may be a portion of the first conductive line 110 or may be electrically connected to the first conductive line 110. The upper electrode pattern 135 may be positioned on the lower electrode pattern 131. The upper electrode pattern 135 may be a portion of the second conductive line 120 or may be electrically connected to the second conductive line 120. The variable resistance pattern 133 may be positioned between the lower electrode pattern 131 and the upper electrode pattern 135.

The upper electrode pattern 135 may include a first portion 135A, a second portion 135B, and a third portion 135C. The first portion 135A may be positioned between the variable resistance pattern 133 and the second conductive line 120. The second portion 135B may extend along sidewalls facing in the second direction II of the upper electrode pattern 135 and may surround an interface between the first portion 135A and the variable resistance pattern 133. For example, the second portion 135B includes a pair of second portions 135B spaced apart from each other in the second direction II. These second portions 135B may extend on sidewalls of the variable resistance pattern 133 that face each other and are arranged in the second direction II, such that an interface between the first portion 135A and the variable resistance pattern 133 may be located between the second portions 135B.

The third portion 135C may extend along sidewalls facing in the first direction I of the upper electrode pattern 135 and sidewalls facing in the first direction I of the second conductive line 120, and may surround an interface between the first portion 135A and the variable resistance pattern 133. For example, the third portion 135C includes a pair of third portions 135C spaced apart from each other in the first direction I. These third portions 135C may extend on second sidewalls of the variable resistance pattern 133 that face each other and are arranged in the first direction I, such that the second portions 135B and the third portions 135C of the upper electrode pattern 135 surround the interface between the first portion 135A and the variable resistance pattern 133. The third portions 135C may further extend on sidewalls of the second conductive line 120 that face each other and are arranged in the first direction I.

The second portion 135B and the third portion 135C may contact a sidewall of the variable resistance pattern 133. For example, each of the second portions 135B and the third portions 135C may contact a corresponding one of the first and second sidewalls of the variable resistance pattern 133. The third portion 135C may contact a sidewall of the second conductive line 120. For example, each of the third portions 135C may contact a corresponding one of the sidewalls of the second conductive line 120.

The second portion 135B may have a first height H1 in a cross-section lying in a first plane defined by the second direction II and a third direction III. For example, the second portion 135B includes a pair of portions each having a first height H1 in a cross-section lying in a first plane defined by the second direction II and the third direction III. The third portion 135C may have a second height H2 different from the first height H1 in a cross-section lying in a second plane defined by the first direction I and the third direction III. For example, the third portion 135C includes a pair of portions each having a second height H2 in a cross-section lying in a second plane defined by the first direction I and the third direction III. For example, the third portion 135C may have the second height H2 greater than the first height H1. This is because, in a process of manufacturing the semiconductor device, process timings for forming the second portion 135B and the third portion 135C are different. Here, the third direction III may intersect with the first direction I and the second direction II.

At least one of the lower electrode pattern 131 or the upper electrode pattern 135 may include a material having a selectivity with respect to the variable resistance pattern 133. Specifically, the lower electrode pattern 131, or the upper electrode pattern 135, or both may include a material having an etch rate lower than that of the variable resistance pattern 133. For example, at least one of the lower electrode pattern 131 or the upper electrode pattern 135 may include carbon. Here, the variable resistance pattern 133 may include a chalcogenide material.

The lower electrode pattern 131 or the upper electrode pattern 135 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), and the like, and may include a combination thereof.

The variable resistance pattern 133 may maintain an amorphous state during a program operation and may not change into a crystalline state after the program operation. In other words, a phase of the variable resistance pattern 133 may not change after the program operation.

The variable resistance pattern 133 may be used as a data storage and as a selection element simultaneously. The variable resistance pattern 133 may include a resistive material and may have a characteristic of reversibly changing between different resistance states according to an applied voltage or current. For example, the variable resistance pattern 133 may include a variable resistance material of which a resistance changes without a phase change and may include a chalcogenide element. The variable resistance pattern 133 may include germanium (Ge), antimony (Sb), arsenic (As), silicon (Si), indium (In), tin (Sn), gallium (Ga), and the like, or may include a combination thereof.

The variable resistance pattern 133 may include a phase change material and may include a chalcogenide. The variable resistance pattern 133 may include a chalcogenide glass, a chalcogenide alloy, and the like. A phase of the variable resistance pattern 133 may change according to the program operation. For example, the variable resistance pattern 133 may have a low resistance crystalline state by a set operation. In addition, the variable resistance pattern 133 may have a high resistance amorphous state by a reset operation. Therefore, data may be stored in the memory cell 130 by using a resistance difference according to the phase of the variable resistance pattern 133.

The variable resistance pattern 133 may include a metal oxide (transition metal oxide) or a metal oxide such as a perovskite material. Therefore, as an electrical path is generated or disappeared in the variable resistance pattern 133, data may be stored in the memory cell.

The variable resistance pattern 133 may have an MTJ structure and may include a magnetization fixed layer, a magnetization free layer, and a tunnel barrier layer interposed therebetween. For example, the magnetization fixed layer and the magnetization free layer may include a magnetic material, and the tunnel barrier layer may include an oxide such as magnesium (Mg), aluminum (Al), zinc (Zn), or titanium (Ti). Here, a magnetization direction of the magnetization free layer may be changed by spin torque of electrons in an applied current. Therefore, data may be stored in the memory cell 130 according to a change in the magnetization direction of the magnetization free layer with respect to a magnetization direction of the magnetization fixed layer.

In addition, the variable resistance pattern 133 may have a metal insulator metal (MIM) structure including a metal oxide. In this case, data may be stored in the memory cell 130 by using a resistance change of the metal oxide which occurs by applying a short electric pulse.

For reference, although not shown in this drawing, the semiconductor device may further include an intermediate electrode pattern and a switching pattern. For example, the semiconductor device may include a structure in which the lower electrode pattern 131, the switching pattern, the intermediate electrode pattern, the variable resistance pattern 133, and the upper electrode pattern 135 are sequentially stacked. In this case, the lower electrode pattern 131, the switching pattern, and the intermediate electrode pattern may configure a selection element. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching pattern 123 may include a chalcogenide material. In addition, the intermediate electrode pattern, the variable resistance pattern 133, and the upper electrode pattern 135 may configure a memory element. The memory element and the selection element may share the intermediate electrode pattern.

The first liner patterns 140 may surround a sidewall of the memory cell 130 neighboring in the second direction II along a profile of the memory cell 130. For example, a first liner pattern 140 may cover a sidewall of the memory cell 130 along a profile of the memory cell 130, where the memory cell 130 is adjacent to the first liner pattern 140 in the second direction II. The second liner patterns 150 may be positioned on the first liner patterns 140 and may extend along a sidewall of the first conductive line 110. Specifically, a second line pattern 150 may be positioned on the first line pattern 140 and extend along a sidewall of the first conductive line 110. For example, the second liner patterns 150 may extend along sidewalls neighboring in the second direction II of the first conductive line 110.

A pair of a first liner pattern 140 and a second liner pattern 150 may include a first bend portion V1 covering a lower surface of the second portion 135B of the upper electrode pattern 135. Here, the first bend portion V1 may refer to a region where the profile of the memory cell 130 changes by the second portion 135B of the upper electrode pattern 135, as a region adjacent to an upper surface of the variable resistance pattern 133. For reference, the region adjacent to the upper surface of the variable resistance pattern 133 may refer to a region adjacent to the upper electrode pattern 135 with respect to an intermediate portion of the variable resistance pattern 133.

The pair of first liner pattern 140 and second liner pattern 150 may have a first thickness T1 in a region adjacent to the upper electrode pattern 135, and may have a second thickness T2 greater than the first thickness T1 at the first bend portion V1. Here, the first and second thicknesses T1 and T2 may refer to thicknesses at which the pair of first liner pattern 140 and second liner pattern 150 extend in the second direction II. That is, because the pair of first liner pattern 140 and second liner pattern 150 are formed along the profile of the memory cell 130, the pair of first liner pattern 140 and second liner pattern 150 may have the second thickness T2 relatively great in the first direction I at the first bend portion V1.

The third liner pattern 170 may cover a sidewall of the memory cell 130 along the profile of the memory cell 130. For example, the third liner patterns 170 may respectively cover sidewalls neighboring in the first direction I of the memory cell 130.

The third liner pattern 170 may include a second bend portion V2 covering a lower surface of the second portion 135B of the upper electrode pattern 135. Here, the second bend portion V2 may refer to a portion where the profile of the memory cell 130 changes by the third portion 135C of the upper electrode pattern 135, as a region adjacent to the upper surface of the variable resistance pattern 133. The third liner pattern 170 may have a third thickness T3 in a region adjacent to the upper electrode pattern 135, and may have a fourth thickness T4 greater than the third thickness T3 at the second bend portion V2. Here, the third and fourth thicknesses T3 and T4 may refer to thicknesses at which the third liner pattern 170 extends in the first direction I.

The first liner patterns 140, the second liner patterns 150, and the third liner patterns 170 may protect the memory cells 130 in the process of manufacturing the semiconductor device. At least one of the first liner patterns 140, the second liner patterns 150, or the third liner patterns 170 may include a nitride. The nitride may be subjected to a compressive force. Therefore, because the pair of first liner pattern 140 and second liner pattern 150 may have a relatively great second thickness T2 at the first bend portion V1 than a region adjacent to the upper electrode pattern 135, the pair of first liner pattern 140 and second liner pattern 150 may exert a relatively great compressive force, and because the third liner pattern 170 may have a relatively great fourth thickness T4 at the second bend portion V2 than a region adjacent to the upper electrode pattern 135, the third liner pattern 170 may exert a relatively great compressive force.

In a conventional semiconductor device, when the memory cell repeatedly performs program and erase operations, a material included in the variable resistance pattern may be diffused to an outside, and reliability of the memory cell may be deteriorated. For example, when the memory cell repeatedly performs an operation, a volume of a region adjacent to the upper surface of the variable resistance pattern may be expanded. As another example, a chalcogenide element included in the variable resistance pattern may be separated from the variable resistance pattern and may move toward the upper electrode pattern. In particular, the chalcogenide element may be separated from in a region adjacent to the upper surface of the variable resistance pattern. In this case, the chalcogenide element may move along an interface of the upper electrode pattern and the first/third liner patterns including different materials, an adhesive force between the upper electrode pattern and the first/third liner patterns may be weakened, and a gap may occur between the upper electrode pattern and the first/third liner patterns.

According to an embodiment of the present disclosure, the upper electrode pattern 135 may cover a region adjacent to the upper surface of the variable resistance pattern 133 in a hat shape. For example, the upper electrode pattern 135 may have a substantially trapezoidal shape in a cross-section. The upper surface of the variable resistance pattern 133 may be covered by the first portion 135A, and sidewalls of a region adjacent to the upper surface of the variable resistance pattern 133 may be covered by the second and third portions 135B and 135C. Therefore, because the upper electrode pattern 135 covers the region adjacent to the upper surface of the variable resistance pattern 133 in the hat shape, an expansion of a volume of the region adjacent to the upper surface of the variable resistance pattern 133 may be prevented or reduced.

When the second/third portions 135B and 135C of the upper electrode pattern 135 does not exist, the first portion 135A and the first/third liner patterns 140 and 170 may contact, and the chalcogenide element may move through a relatively short path along an interface of the upper electrode pattern 135 and the first/third liner patterns 140 and 170. On the other hand, according to an embodiment of the present disclosure, because the chalcogenide element is required to move along the interface between the second/third portions 135B and 135C and the variable resistance pattern 133 and then move to the interface between the second/third portions 135B and 135C and the first/third liner patterns 140 and 170, the chalcogenide element is required to move through a relatively long path. By increasing a movement path of the chalcogenide element as described above, separation of the chalcogenide element from the variable resistance pattern 133 may be reduced. Therefore, deterioration of reliability of the memory cell 130 may be prevented or reduced.

In addition, according to an embodiment of the present disclosure, the first and second liner patterns 140 and 150 may have the relatively great second thickness T2 at the first bend portion V1, and the third liner patterns 170 may have the relatively great fourth thickness T4 at the second bend portion V2. In addition, the first, second, and third liner patterns 140, 150, and 170 may include a nitride, and the nitride may exert a compressive force. In this case, the first and second liner patterns 140, 150 may exert a relatively great compressive force at the first bend portion V1, and the third liner patterns 170 may exert a relatively great compressive force at the second bend portion V2. In other words, because the first, second and third liner patterns 140, 150, and 170 may apply a relatively great compressive force to the upper electrode pattern 135 in the region adjacent to the upper surface of the variable resistance pattern 133, an adhesive force between the upper electrode pattern 135 and the first and third liner pattern 140 and 170 may increase. Therefore, the first, second and third liner patterns 140, 150, and 170 may prevent or reduce occurrence of a gap between the upper electrode pattern 135 and the first and third liner pattern 140 and 170.

The first gap-fill patterns 160 may be positioned between the memory cells 130. For example, the first gap-fill patterns 160 may be positioned between the memory cells 130 neighboring in the second direction II. The first and second liner patterns 140 and 150 may be positioned between the first gap-fill patterns 160 and the memory cells 130. The first gap-fill patterns 160 may include an insulating material such as an oxide.

The second gap-fill patterns 180 may be positioned between the memory cells 130. For example, the second gap-fill patterns 180 may be positioned between the memory cells 130 neighboring in the first direction I. The third liner patterns 170 may be positioned between the second gap-fill patterns 180 and the memory cells 130. The second gap-fill patterns 180 may include an insulating material such as an oxide.

According to the structure described above, the upper electrode pattern 135 may cover the region adjacent to the upper surface (or an upper portion) of the variable resistance pattern 133 in the hat shape. As a result, the path through which the chalcogenide element included in the variable resistance pattern 133 is required to move may be increased by the shape of the upper electrode pattern 135. In addition, the region adjacent to the upper surface of the variable resistance pattern 133 may be limited from expanding, and occurrence of the gap between the upper electrode pattern 135 and the first/third liner patterns 140 and 170 may be prevented or reduced.

In addition, the first, second, and third liner patterns 140, 150, and 170 may include a nitride, and may have the relatively large second and fourth thicknesses T2 and T4 in the region adjacent to the upper surface of the variable resistance pattern 133. Therefore, occurrence of the gap between the upper electrode pattern 135 and the first/third liner patterns 140 and 170 may be prevented or reduced.

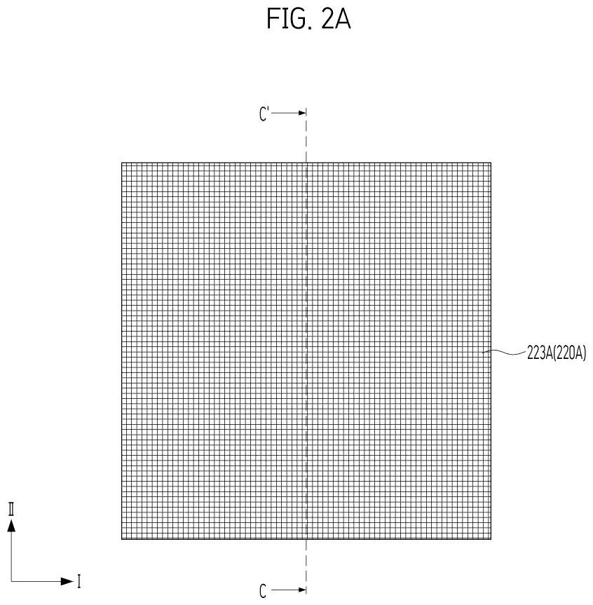

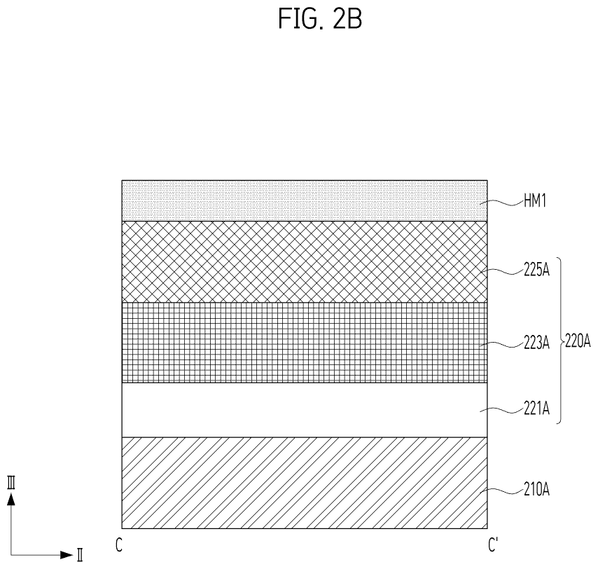

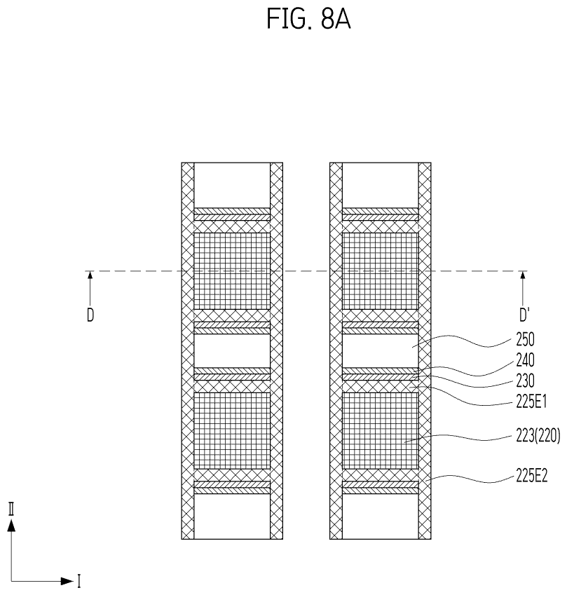

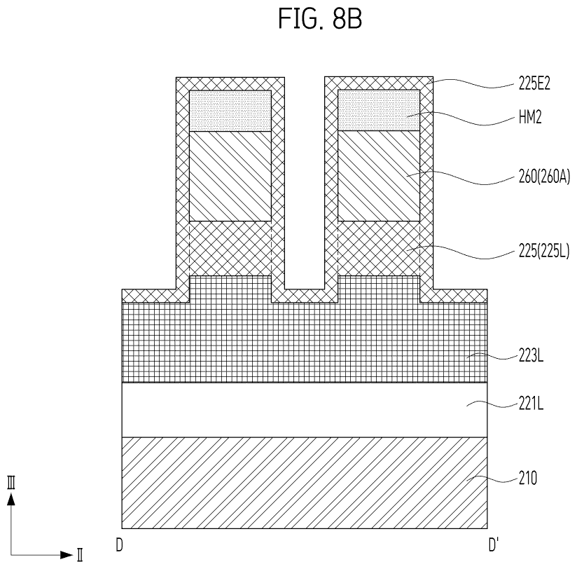

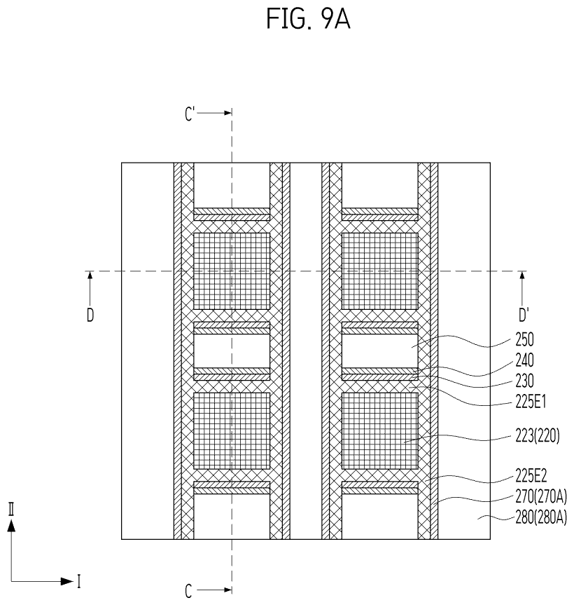

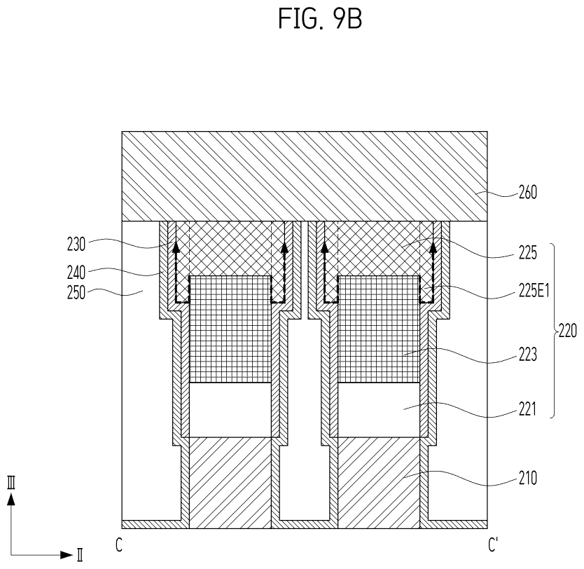

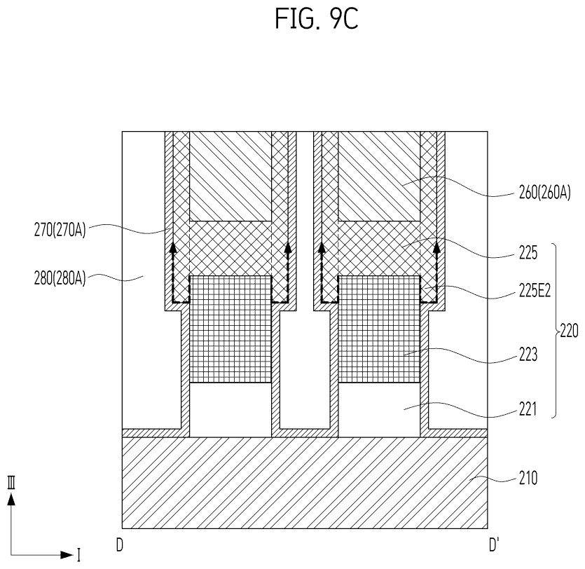

FIGS. 2A to 9C are drawings illustrating a method of manufacturing a semiconductor device according to an embodiment of the present disclosure. FIGS. 2A, 3A, 4A, 5A, 6A, 7A, and 8A are plan views, and FIGS. 2B, 3B, 4B, 5B, 6B, 7B, and 9B are cross-sectional views taken along line C-C′ of FIGS. 2A, 3A, 4A, 5A, 6A, 7A, and 9A, respectively. FIGS. 8B and 9C are cross-sectional views taken along line D-D′ of FIGS. 8A and 9A, respectively. Hereinafter, a content overlapping the content described above may be omitted for the interest of brevity.

Referring to FIGS. 2A and 2B, a memory layer 220A including a variable resistance layer 223A may be formed on a first conductive layer 210A. First, a lower electrode layer 221A may be formed on the first conductive layer 210A. Subsequently, the variable resistance layer 223A may be formed on the lower electrode layer 221A. Subsequently, an upper electrode layer 225A may be formed on the variable resistance layer 223A.

The upper electrode layer 225A may include a material different from that of the variable resistance layer 223A. The upper electrode layer 225A may include a material having a selectivity with respect to the variable resistance layer 223A. Specifically, the upper electrode layer 225A may include a material having an etch rate lower than that of the variable resistance layer 223A. For example, the upper electrode layer 225A may include carbon, and the variable resistance layer 223A may include a chalcogenide material.

For reference, although not shown in this drawing, the memory layer 220A may be formed by sequentially stacking the lower electrode layer 221A, a switching layer, an intermediate electrode layer, the variable resistance layer 223A, and the upper electrode layer 225A.

Subsequently, a first hard mask pattern HM1 may be formed on the memory layer 220A. Here, the first hard mask pattern HM1 may be formed as a single layer or multiple layers. For example, the first hard mask pattern HM1 may be formed as multiple layers by sequentially stacking a nitride, an oxide, and a nitride. The first hard mask pattern HM1 may prevent or reduce damage to the memory layer 220A in a subsequent process as a protective pattern.

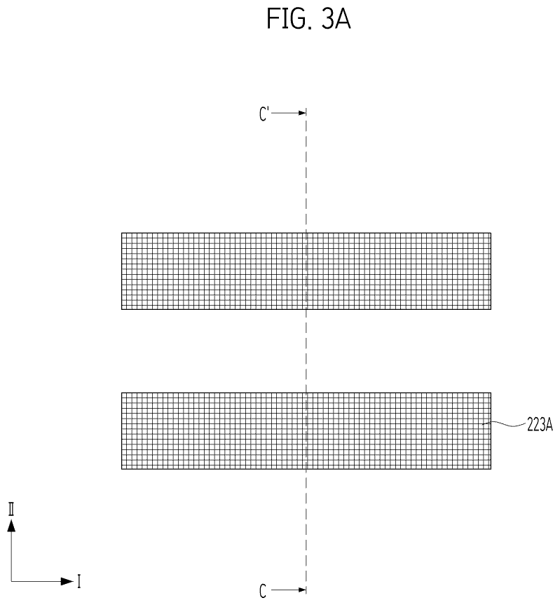

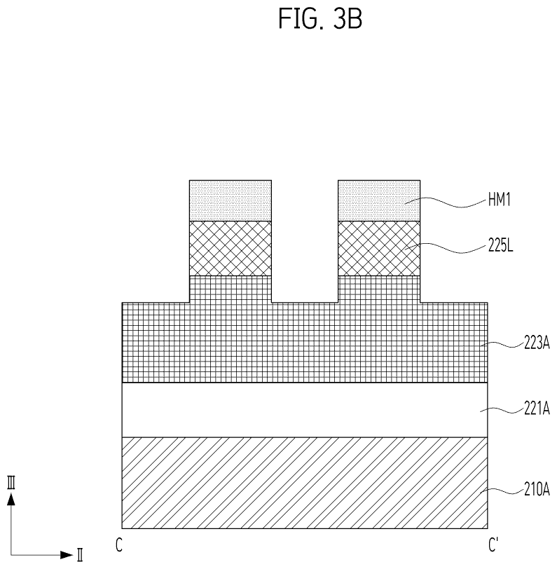

Referring to FIGS. 3A and 3B, the upper electrode layer 225A may be etched to form upper electrode lines 225L extending in the first direction I. For example, the upper electrode layer 225A may be etched through the first hard mask pattern HM1 to form the upper electrode lines 225L each extending in the first direction I.

Subsequently, the variable resistance layer 223A may be etched to a partial thickness. For example, the variable resistance layer 223A may be etched to a partial thickness through the first hard mask pattern HM1 to form trenches each extending in the first direction I. Specifically, the variable resistance layer 223A may be partially etched to form trenches each having a given depth. The variable resistance layer 223A may be etched in a region adjacent to an upper surface. Here, the region adjacent to the upper surface of the variable resistance layer 223A may refer to a region adjacent to an upper electrode line 225L with respect to an intermediate portion of the variable resistance layer 223A. The variable resistance layer 223A may be etched to a desired thickness by controlling a process environment, such as a time for etching the variable resistance layer 223A.

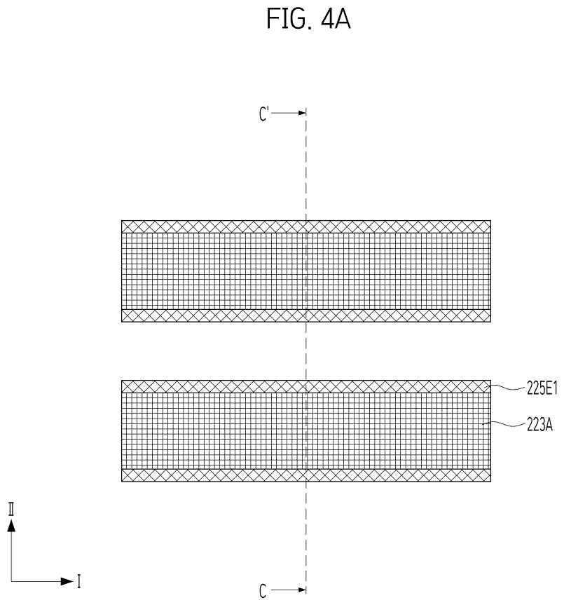

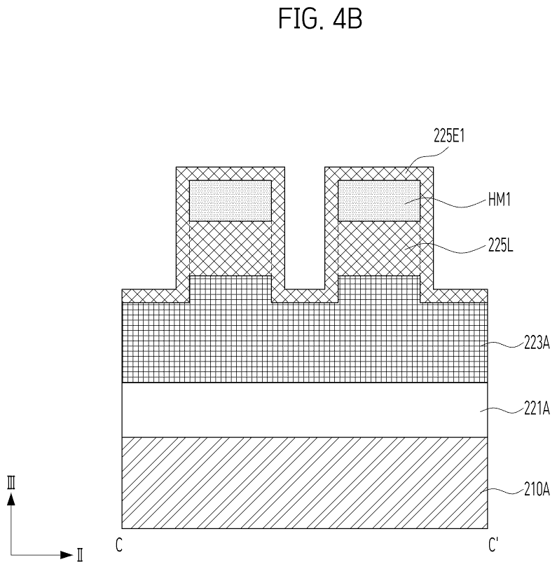

Referring to FIGS. 4A and 4B, a first additional electrode layer 225E1 may be formed. For example, the first additional electrode layer 225E1 may be formed along a profile of the upper electrode lines 225L and the variable resistance layer 223A. The first additional electrode layer 225E1 may extend on sidewalls of the upper electrode lines 225L neighboring in the second direction II and the trenches formed in the variable resistance layer 223A.

The first additional electrode layer 225E1 may include a material having a selectivity with respect to the variable resistance layer 223A. For example, the first additional electrode layer 225E1 may include carbon. The first additional electrode layer 225E1 may include the same material as the upper electrode layer 225A. In other words, the first additional electrode layer 225E1 may include a material common with that of the upper electrode layer 225A. Therefore, an interface between the first additional electrode layer 225E1 and the upper electrode lines 225L may not exist, and the first additional electrode layer 225E1 may be used as a single upper electrode layer integrated with the upper electrode lines 225L.

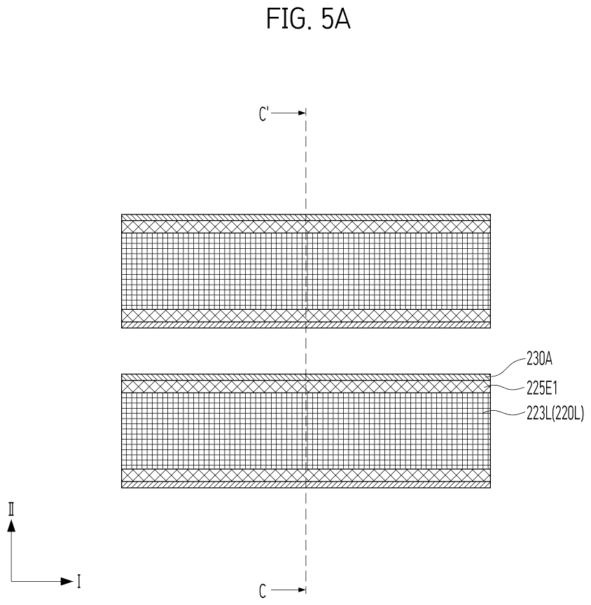

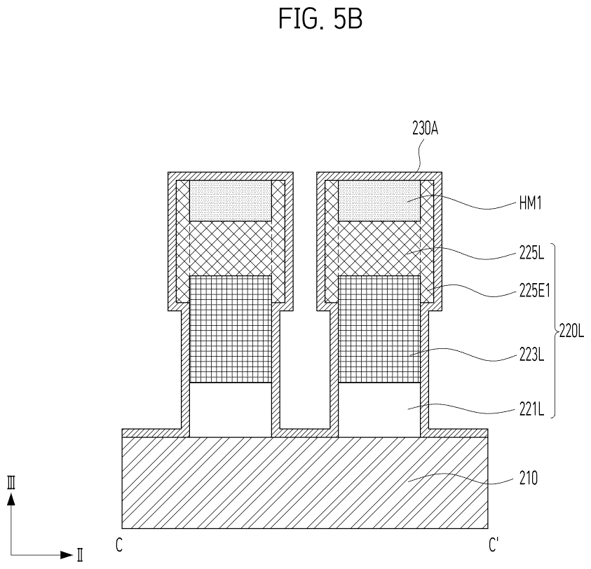

Referring to FIGS. 5A and 5B, variable resistance lines 223L may be formed. For example, the variable resistance layer 223A may be further etched to form the variable resistance lines 223L. First, portions of the first additional electrode layer 225E1, each of which is formed between an adjacent pair of the upper electrode lines 225L arranged in the second direction II, may be etched to expose the variable resistance layer 223A. In other words, portions of the first additional electrode layer 225E1 contacting the upper surface of the variable resistance layer 223A may be etched to expose the variable resistance layer 223A. Subsequently, the variable resistance layer 223A may be selectively etched to form the variable resistance lines 223L. Because the variable resistance layer 223A includes a material having a selectivity with respect to the upper electrode lines 225L (e.g., the variable resistance layer 223A includes a material having an etch rate higher than that of the upper electrode lines 225L), the variable resistance layer 223A may be selectively etched. At this time, a portion of the first additional electrode layer 225E1 may remain to cover a region adjacent to an upper surface of the variable resistance lines 223L. In other words, remaining portions of the etched first additional electrode lines 225E1 each cover a sidewall of an upper portion of the variable resistance line 223L.

Subsequently, the lower electrode layer 221A may be etched to form lower electrode lines 221L. Accordingly, a memory line 220L including the lower electrode line 221L, the variable resistance line 223L, and the upper electrode line 225L may be formed.

Subsequently, a first liner layer 230A may be formed along a profile of the etched first additional electrode layer 225E1 (e.g. remaining portions of the first additional electrode layer 225E1 in FIG. 4B, after its portions each formed between an adjacent pair of the upper electrode lines 225L have been etched as described above), the variable resistance lines 223L, the lower electrode lines 221L, and the first conductive layer 210A. Here, the first liner layer 230A may have a bend portion that covers the remaining portion of the first additional electrode layer 225E1 adjacent to the upper surface of the variable resistance lines 223L. The first liner layer 230A may include a nitride.

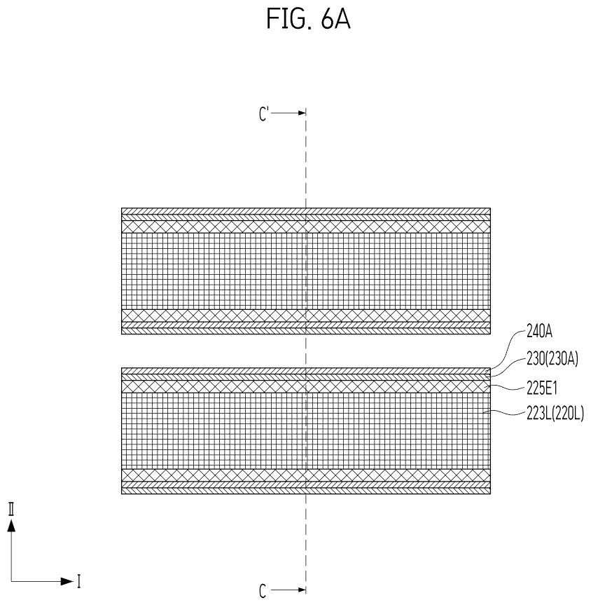

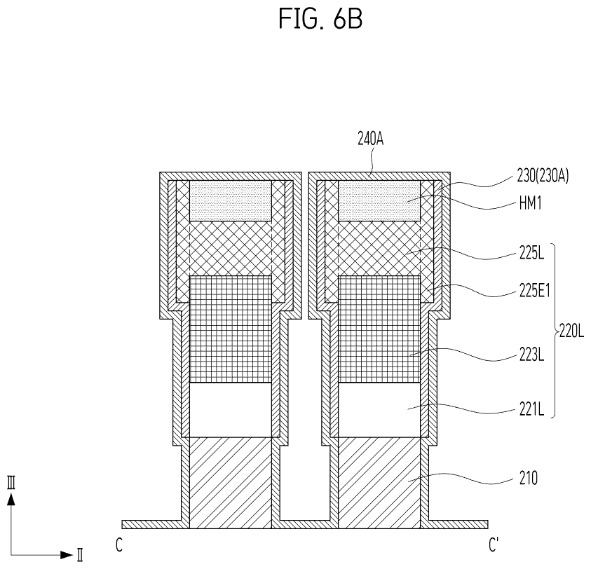

Referring to FIGS. 6A and 6B, the first conductive layer 210A may be etched to form first conductive lines 210 each extending in the first direction I. First, the first liner layer 230A may be etched to form first liner patterns 230. For example, the first liner patterns 230 may be formed by etching portions of the first liner layer 230A that contact an upper surface of the first conductive layer 210A and portions of the first liner layer 230A that contact upper surfaces of the first hard mask pattern HM1. Subsequently, portions of the first conductive layer 210A exposed between the first liner patterns 230 may be etched to form the first conductive lines 210 each extending in the first direction I.

Subsequently, a second liner layer 240A extending along the first conductive lines 210 may be formed on the first liner patterns 230. For example, the second liner layer 240A may extend on the first liner patterns 230 and sidewalls of the first conductive lines 210. Here, because the second liner layer 240A is formed on the first liner patterns 230, the second liner layer 240A may have a bend portion covering the region of the first additional electrode layer 225E1 adjacent to the upper surface of the variable resistance lines 223L. The second liner layer 240A may include a material that is the same as or different from that of the first liner layer 230A. For example, the second liner layer 240A may include a nitride.

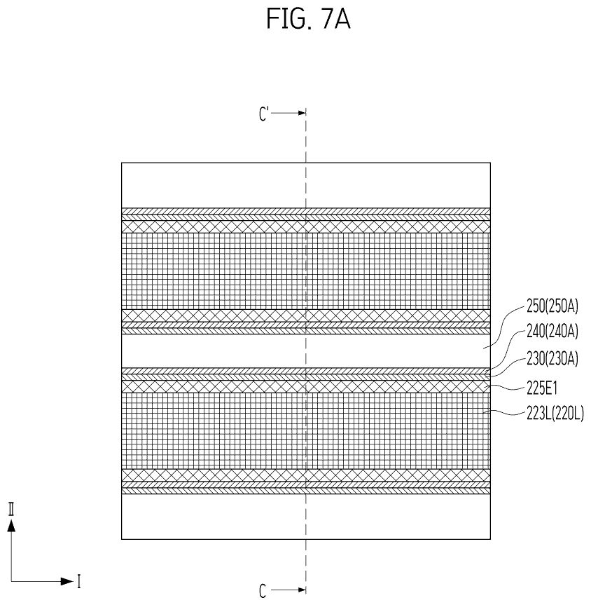

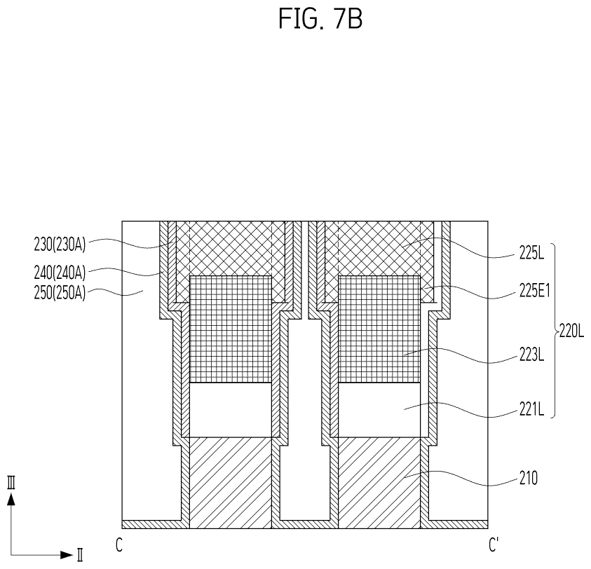

Referring to FIGS. 7A and 7B, a first gap fill layer 250A that fills a space between the memory lines 220L may be formed. Here, the first gap fill layer 250A may include an insulating material such as an oxide.

Subsequently, planarization may be performed so that an upper surface of the upper electrode lines 225L is exposed. For example, the first gap fill layer 250A, the second liner layer 240A, and the first hard mask pattern HM1 may be removed by performing planarization so that the upper surface of the upper electrode lines 225L is exposed. At this time, the second liner layer 240A may be separated into second liner patterns 240, and the first gap fill layer 250A may be separated into first gap fill patterns 250.

Referring to FIGS. 8A and 8B, second conductive lines 260 each extending in the second direction II that intersects the first direction I may be formed on the upper electrode lines 225L. First, a second conductive layer 260A may be formed on the upper electrode lines 225L. Subsequently, the second hard mask pattern HM2 may be formed on the second conductive layer 260A. Here, the second hard mask pattern HM2 may have substantially the same shape as the first hard mask pattern HM1 and may include the same material as the first hard mask pattern HM1. Subsequently, the second conductive layer 260A may be etched through the second hard mask pattern HM2 to form the second conductive lines 260 each extending in the second direction II.

Subsequently, the upper electrode lines 225L may be etched to form upper electrode patterns 225. For example, the upper electrode lines 225L may be etched through the second hard mask pattern HM2 to form the upper electrode patterns 225.

Subsequently, the variable resistance lines 223L may be etched to a partial thickness. For example, the variable resistance lines 223L may be etched to a partial thickness through the second hard mask pattern HM2. Specifically, the variable resistance lines 223L may be partially etched to form trenches each having a given depth. Here, a method of etching the variable resistance lines 223L to a partial thickness may be substantially the same as a method of etching the variable resistance layer 223A to a partial thickness in FIGS. 3A and 3B.

Subsequently, a second additional electrode layer 225E2 may be formed along a profile of the second conductive lines 260, the upper electrode patterns 225, and the variable resistance lines 223L. The second additional electrode layer 225E2 may include a material having a selectivity with respect to the variable resistance layer 223A. For example, the second additional electrode layer 225E2 may include carbon. The second additional electrode layer 225E2 may include the same material as the upper electrode layer 225A. Therefore, an interface may not exist between the first additional electrode layer 225E1, the second additional electrode layer 225E2, and the upper electrode pattern 225. The first additional electrode layer 225E1 and the second additional electrode layer 225E2 may be used as a single upper electrode pattern integrated with the upper electrode layer 225A.

Referring to FIGS. 9A and 9B, a variable resistance pattern 223 may be formed. For example, the variable resistance lines 223L may be etched to form the variable resistance patterns 223. First, portions of the second additional electrode layer 225E2, each of which is formed between an adjacent pair of the upper electrode patterns 225 arranged in the second direction II, may be etched to expose the variable resistance lines 223L. Subsequently, the variable resistance lines 223L may be selectively etched to form the variable resistance patterns 223. At this time, a portion of the second additional electrode layer 225E2 may remain and cover a region adjacent to an upper surface of the variable resistance patterns 223.

According to an embodiment of the present disclosure, the first and second additional electrode layers 225E1 and 225E2 may cover the region adjacent to the upper surface of the variable resistance patterns 223. For example, the first additional electrode layer 225E1 may partially cover sidewalls of the variable resistance patterns 223 neighboring in the second direction II, and the second additional electrode layer 225E2 may partially cover sidewalls of the variable resistance patterns 223 neighboring in the first direction I. In other words, the first and second additional electrode layers 225E1 and 225E2 and the upper electrode pattern 225 configuring a single upper electrode pattern may cover the region adjacent to the upper surface of the variable resistance pattern 223 in a hat shape. In this case, expansion of a volume of the region adjacent to the upper surface of the variable resistance pattern 223 due to repeated operations of the memory cell 220 may be prevented or reduced.

In addition, even though the chalcogenide element is separated due to operation repetition performance of the memory cell 220, the chalcogenide element is required to move along an interface between the first and second additional electrode layers 225E1 and 225E2 and the variable resistance pattern 223, and then move to an interface between the first and second additional electrode layers 225E1 and 225E2 and the first and third liner patterns 240 and 270 in order to move along a relatively long path. According to an embodiment of the present disclosure, by increasing a movement path of the chalcogenide element as described above, separation of the chalcogenide element from the variable resistance pattern 223 may be reduced. Therefore, deterioration of reliability of the memory cell 220 may be prevented or reduced.

Subsequently, the lower electrode lines 221L may be etched to form lower electrode patterns 221. Accordingly, the memory cell 220 including the lower electrode pattern 221, the variable resistance pattern 223, and the upper electrode pattern 225 may be formed.

Subsequently, a third liner layer 270A may be formed along a profile of the second conductive lines 260, the etched second additional electrode layer 225E2 (e.g., remaining portions of the second additional electrode layer 225E2 in FIG. 8B, after its portions each formed between an adjacent pair of the upper electrode patterns 225 have been etched as described above), the variable resistance patterns 223, the lower electrode patterns 221, and the first conductive lines 210. Here, the third liner layer 270A may have a bend portion that covers the remaining portion of the second additional electrode layer 225E2 adjacent to the upper surface of the variable resistance patterns 223. The third liner layer 270A may include a nitride.

Subsequently, a second gap fill layer 280A that fills a space between the memory cells 220 may be formed. Here, the second gap fill layer 280A may include an insulating material such as an oxide.

Subsequently, planarization may be performed so that upper surfaces of the second conductive lines 260 are exposed. For example, the second gap fill layer 280A, the third liner layer 270A, and the second hard mask pattern HM2 may be removed so that the upper surfaces of the second conductive lines 260 are exposed. At this time, the third liner layer 270A may be separated into third liner patterns 270, and the second gap fill layer 280A may be separated into second gap fill patterns 280.

According to an embodiment of the present disclosure, by forming the first additional electrode layer 225E1 on the upper electrode lines 225L, the first liner layer 230A and the second liner layer 240A may include a bend portion. Similarly, by forming the second additional electrode layer 225E2 on the upper electrode patterns 225, the third liner layer 270A may include a bend portion. The first, second, and third liner layers 230A, 240A, and 270A may include a nitride, and the nitride may exert a compressive force. In other words, a pair of first and second liner layers 230A and 240A may exert a relatively great compressive force at the bend portion, and the third liner layer 270A may exert a relatively great compressive force at the bend portion. In this case, an adhesive force between the first/second additional electrode layers 225E1 and 225E2 and the first/third liner layers 230A and 270A may increase. Therefore, the first, second and third liner layers 230A, 240A, and 270A may prevent or reduce occurrence of a gap between the first/second additional electrode layers 225E1 and 225E2 and the first/third liner layers 230A and 270A.

According to the manufacturing method described above, the first additional electrode layer 225E1 covering the region adjacent to the upper surface of the variable resistance line 223L may be formed on the upper electrode line 225L, and the second additional electrode layer 225E2 covering the region adjacent to the upper surface of the variable resistance pattern 223 may be formed on the upper electrode pattern 225. The first and second additional electrode layers 225E1 and 225E2 may be used as a single upper electrode pattern integrated with the upper electrode pattern 225. Accordingly, the upper electrode pattern may be formed in a hat shape that may cover the region adjacent to the upper surface of the variable resistance pattern 223. Therefore, even though the operation of the memory cell 220 is repeatedly performed, a volume of the variable resistance pattern 223 may be limited from expanding, the chalcogenide element included in the variable resistance pattern 223 may be prevented from being separated, and thus reliability of the memory cell 220 may be ensured.

In addition, the first and second liner layers 230A and 240A including a bend portion may be formed on the first additional electrode layer 225E1, and the third liner layer 270A including a bend portion may be formed on the second additional electrode layer 225E2. Here, the first, second, and third liner layers 270A may include a nitride. Because the first, second, and third liner layers 270A may be formed to have a relatively great thickness at the bend portion as the first and second additional electrode layers 225E1 and 225E2 are formed, occurrence of a gap between the first/second additional electrode layers 225E1 and 225E2 and the first/third liner layers 230A and 270A may be prevented or reduced.

Although some embodiments of the present disclosure have been described above with reference to the accompanying drawings, various embodiments of the present disclosure are not limited to the above-described embodiments. Various forms of substitution, modification, and change of the embodiments may be possible by those skilled in the art to which the present disclosure belongs.

What is claimed is:

1. A semiconductor device comprising:
a first conductive line extending in a first direction;
a second conductive line positioned on the first conductive line and extending in a second direction that intersects the first direction; and
a memory cell positioned between the first conductive line and the second conductive line, and including a lower electrode pattern, an upper electrode pattern positioned on the lower electrode pattern, and a variable resistance pattern positioned between the lower electrode pattern and the upper electrode pattern,
wherein the upper electrode pattern comprises:
a first portion positioned between the variable resistance pattern and the second conductive line; and
a pair of second portions extending on first sidewalls of the variable resistance pattern that face each other and are arranged in the second direction, such that an interface between the first portion and the variable resistance pattern is located between the second portions.

2. The semiconductor device of claim 1, wherein the upper electrode pattern further comprises a pair of third portions extending on second sidewalls of the variable resistance pattern that face each other and are arranged in the first direction, such that the second portions and the third portions of the upper electrode pattern surround the interface between the first portion and the variable resistance pattern, and
wherein the third portions further extend on sidewalls of the second conductive line that face each other and are arranged in the first direction.

3. The semiconductor device of claim 2, wherein each of the third portions contacts a corresponding one of the second sidewalls of the variable resistance pattern and contacts a corresponding one of the sidewalls of the second conductive line.

4. The semiconductor device of claim 2, wherein each of the second portions has a first height in a cross-section lying in a first plane defined by the second direction and a third direction,
wherein each of the third portions has a second height greater than the first height in a cross-section lying in a second plane defined by the first direction and the third direction, and
wherein the third direction intersects the first direction and the second direction.

5. The semiconductor device of claim 1, wherein the first portion contacts an upper surface of the variable resistance pattern, and
wherein each of the second portions contacts a corresponding one of the first sidewall of the variable resistance pattern.

6. The semiconductor device of claim 1, further comprising:
a first liner pattern covering a sidewall of the memory cell along a profile of the memory cell, the memory cell being adjacent to the first liner pattern in the second direction; and
a second liner pattern positioned on the first liner pattern and extending along a sidewall of the first conductive line.

7. The semiconductor device of claim 6, wherein a pair of the first liner pattern and the second liner pattern includes a bend portion covering a lower surface of a corresponding one of the second portions.

8. The semiconductor device of claim 7, wherein the pair of the first liner pattern and the second liner pattern has a first thickness in a region adjacent to the upper electrode pattern, and
wherein the pair of first liner pattern and second liner pattern has a second thickness in the bend region, the second thickness being greater than the first thickness.

9. The semiconductor device of claim 6, wherein at least one of the first liner pattern or the second liner pattern includes a nitride.

10. The semiconductor device of claim 1, wherein the upper electrode pattern includes a material having a selectivity with respect to the variable resistance pattern.

11. The semiconductor device of claim 10, wherein the upper electrode pattern includes carbon, and
wherein the variable resistance pattern includes a chalcogenide material.

12. A semiconductor device comprising:
a first conductive line extending in a first direction;
a second conductive line positioned on the first conductive line and extending in a second direction that intersects the first direction; and
a memory cell positioned between the first conductive line and the second conductive line, and including a lower electrode pattern, an upper electrode pattern positioned on the lower electrode pattern, and a variable resistance pattern positioned between the lower electrode pattern and the upper electrode pattern,
wherein the upper electrode pattern comprises:
a first portion positioned between the variable resistance pattern and the second conductive line;
a pair of second portions extending on first sidewalls of the variable resistance pattern that face each other and are arranged in the second direction; and
a pair of third portions extending on second sidewalls of the variable resistance pattern that face each other and are arranged in the first direction, and on sidewalls of the second conductive line that face each other and are arranged in the first direction, and
wherein the second portions and the third portions of the upper electrode pattern surround an interface between the first portion and the variable resistance pattern.

13. The semiconductor device of claim 12, wherein the first portion contacts an upper surface of the variable resistance pattern, and
wherein each of the second portions contacts a corresponding one of the first sidewalls of the variable resistance pattern.

14. The semiconductor device of claim 12, wherein each of the third portions contacts a corresponding one of the sidewalls of the second conductive line.

15. The semiconductor device of claim 12, wherein each of the second portions has a first height in a cross-section lying in a first plane defined by the second direction and a third direction,
wherein each of the third portions has a second height greater than the first height in a cross-section lying in a second plane defined by the second direction and the third direction, and
wherein the third direction intersects the first direction and the second direction.

16. The semiconductor device of claim 12, further comprising:
a first liner pattern covering a sidewall of the memory cell along a profile of the memory cell, the sidewall of the memory cell being adjacent to the first liner pattern in the second direction; and
a second liner pattern positioned on the first liner patterns and extending along a sidewall of the first conductive line.

17. The semiconductor device of claim 16, wherein a pair of the first liner pattern and the second liner pattern includes a bend portion covering a lower surface of a corresponding one of the second portions.

18. The semiconductor device of claim 17, wherein the pair of first liner pattern and the second liner pattern has a first thickness in a region adjacent to the upper electrode pattern, and
wherein the pair of first liner pattern and the second liner pattern has a second thickness in the bend portion, the second thickness being greater than the first thickness.

19. The semiconductor device of claim 16, wherein at least one of the first liner pattern or the second liner pattern includes a nitride.

20. The semiconductor device of claim 12, wherein the upper electrode pattern includes a material having a selectivity with respect to the variable resistance pattern.

21. The semiconductor device of claim 20, wherein the upper electrode pattern includes carbon, and
wherein the variable resistance pattern includes a chalcogenide material.

22. A method of manufacturing a semiconductor device, the method comprising:
sequentially forming a lower electrode layer, a variable resistance layer, and an upper electrode layer on a first conductive layer;
forming upper electrode lines each extending in a first direction by etching the upper electrode layer;
partially etching the variable resistance layer;
forming a first additional electrode layer along a profile of the upper electrode lines and the variable resistance layer; and
forming variable resistance lines by further etching the variable resistance layer.

23. The method of claim 22, wherein forming the variable resistance lines comprises:
exposing the variable resistance layer by etching portions of the first additional electrode layer each formed between an adjacent pair of the upper electrode lines; and
forming the variable resistance lines by selectively etching the variable resistance layer.

24. The method of claim 23, wherein the first additional electrode layer includes a material that is common with that of the upper electrode layer, and
wherein the first additional electrode layer includes a material having a selectivity with respect to the variable resistance layer.

25. The method of claim 24, wherein the first additional electrode layer includes carbon, and
wherein the variable resistance layer includes a chalcogenide material.

26. The method of claim 23, further comprising:
forming lower electrode lines by etching the lower electrode layer;
forming a first liner layer along a profile of the etched first additional electrode layer, the variable resistance lines, the lower electrode lines, and the first conductive layer; and
forming first liner patterns by etching the first liner layer.

27. The method of claim 26, further comprising:
forming first conductive lines each extending in the first direction by etching the first conductive layer; and
forming a second liner layer extending on the first conductive lines and the first liner patterns.

28. The method of claim 27, wherein at least one of the first liner layer or the second liner layer includes a nitride.

29. The method of claim 22, further comprising:
forming second conductive lines each extending in a second direction that intersects the first direction on the upper electrode lines;
forming upper electrode patterns by etching the upper electrode lines;
partially etching the variable resistance lines;
forming a second additional electrode layer along a profile of the second conductive lines, the upper electrode patterns, and the variable resistance lines; and
forming variable resistance patterns by further etching the variable resistance lines.

30. The method of claim 29, further comprising:
exposing the variable resistance lines by etching portions of the second additional electrode layer each formed between an adjacent pair of the upper electrode patterns; and
forming the variable resistance patterns by selectively etching the variable resistance lines.

31. The method of claim 29, wherein the second additional electrode layer includes a material common with that of the upper electrode layer, and
wherein the second additional electrode layer includes a material having a selectivity with respect to the variable resistance layer.

32. The method of claim 31, wherein the second additional electrode layer includes carbon, and
wherein the variable resistance layer includes a chalcogenide material.

33. The method of claim 30, further comprising:
forming lower electrode patterns by etching the lower electrode lines; and
forming a third liner layer along a profile of the second conductive lines, the etched second additional electrode layer, the variable resistance patterns, the lower electrode patterns, and the first conductive lines.

34. The method of claim 33, wherein the third liner layer includes a nitride.
